(19) United States
(12) Patent Application Publication
(10) Pub. No.: US 2021/0180876 A1
(43) Pub. Date: Jun. 17, 2021

(54) VAPOR CHAMBER

(71) Applicant: Murata Manufacturing Co., Ltd., Nagaokakyo-shi (JP)

(72) Inventors: Keijiro Kojima, Nagaokakyo-shi (JP); Tatsuhiro Numoto, Nagaokakyo-shi (JP); Takeaki Tamayama, Nagaokakyo-shi (JP); Norikazu Kume, Nagaokakyo-shi (JP)

(21) Appl. No.: 17/186,359

(22) Filed: Feb. 26, 2021

Related U.S. Application Data
(63) Continuation of application No. PCT/JP2020/012857, filed on Mar. 24, 2020.

(30) Foreign Application Priority Data
Jun. 21, 2019 (JP) 2019-115877

(51) Int. Cl. F28D 15/04; F28D 15/02

(52) U.S. Cl. CPC F28D 15/04; F28D 15/0283; F28D 15/0233

(57) ABSTRACT

A vapor chamber that includes a housing including a first sheet and a second sheet opposing each other and having respective outer edges of the first sheet and the second sheet joined together; an operation fluid enclosed in the housing; a wick on an inner surface of the first sheet and/or an inner surface of the second sheet; a first pillar on the inner surface of the first sheet and/or the inner surface of the second sheet and that defines a cavity in the housing; and a second pillar on the inner surface of the first sheet and/or the inner surface of the second sheet and configured to prevent the housing from being warped when heated to join the first sheet and the second sheet together.

### CROSS REFERENCE TO RELATED APPLICATIONS

The present application is a continuation of International application No. PCT/JP2020/012857, filed Mar. 24, 2020, which claims priority to Japanese Patent Application No. 2019-115877, filed Jun. 21, 2019, the entire contents of each of which are incorporated herein by reference.

### FIELD OF THE INVENTION

The present invention relates to a vapor chamber.

### BACKGROUND OF THE INVENTION

In recent times, mobile terminals such as smartphones or tablet PCs have been increasing heat generation due to high integration and high performance of devices. As size reduction of products proceeds, heat-generation density increases further. Thus, heat dissipation performs an important role for such products.

Examples of a heat dissipater with high heat dissipation capability include a vapor chamber, which is a planar heat pipe. A vapor chamber has an apparent coefficient of entire thermal conductivity of several to several tens of times higher than that of metals such as copper or aluminum.

As an example of a heat dissipater including a vapor chamber, Patent Document 1 describes a planar heat pipe including a container with a protrusion having a cavity portion defined by two opposing plates at a center portion, and an operation fluid enclosed in the cavity portion. The cavity portion has a wick structure. The protrusion is sealed by laser welding at the outer periphery.

Patent Document 1: Japanese Unexamined Patent Application Publication No. 2016-35348

### SUMMARY OF THE INVENTION

In the planar heat pipe described in Patent Document 1, the protrusion is sealed with laser welding at the periphery. Here, the plates are heated while undergoing laser welding which results in the entirety of the planar heat pipe being undesirably warped.

The present invention has been made in view of these circumstances, and aims to provide a vapor chamber having smaller warpage caused by joining involving heating.

A vapor chamber according to the present invention includes a housing including a first sheet and a second sheet opposing each other and having respective outer edges of the first sheet and the second sheet joined together; an operation fluid enclosed in the housing; a wick on an inner surface of the first sheet and/or an inner surface of the second sheet; a first pillar on the inner surface of the first sheet and/or the inner surface of the second sheet and that defines a cavity in the housing; and a second pillar on the inner surface of the first sheet and/or the inner surface of the second sheet and configured to prevent the housing from being warped when heated to join the first sheet and the second sheet together. The first pillar preferably has an area that is equal to or smaller than 0.05% of an area of the housing in a plan view. The second pillar preferably has an area that is 0.5% to 7.0% of the area of the housing in the plan view. A profile of the vapor chamber in the plan view is in the form of a rectangle or a combination of a plurality of rectangles. The second pillar is located on an inner side of one of the rectangles longest in a longitudinal direction so as to extend in the longitudinal direction of the longest rectangle at a position passing a center point of the longest rectangle. The second pillar has a length in the longitudinal direction of the longest rectangle that is 30% to 70% of the length of the longest rectangle. The second pillar has a width in a width direction of the longest rectangle that is 5% to 10% of the width of the longest rectangle.

The present invention can provide a vapor chamber having smaller warpage caused by joining involving heating.

### BRIEF DESCRIPTION OF THE DRAWINGS

FIG. 1 is a schematic cross-sectional view of an example of a structure of a vapor chamber.

FIG. 2 is a schematic top view of an example of a vapor chamber.

FIGS. 3A, 3B, and 3C are schematic cross-sectional views of an example of a second pillar constituting a vapor chamber.

FIG. 4 is a top view illustrating the positional relationship between the plan-view profile of the vapor chamber and the second pillar.

FIGS. 5A, 5B, 5C, 5D, and 5E are schematic top views of other examples of a vapor chamber.

FIG. 6 is a schematic top view of another example of a vapor chamber.

FIG. 7 is a schematic top view of another example of a vapor chamber.

### DETAILED DESCRIPTION OF THE PREFERRED EMBODIMENTS

A vapor chamber of the present invention will be described, below.

The present invention, however, is not limited to the following structure, and may be changed as appropriate within the scope not departing from the gist of the present invention. A combination of two or more of individual desirable components of the present invention described below is also included in the present invention.

The following embodiments are naturally mere examples, and components of different embodiments may be partially replaced with each other or combined together.

A vapor chamber according to the present invention includes a housing, including first and second sheets opposing each other with their outer edges joined together with a joining operation that includes heating, an operation fluid enclosed in the housing, a wick on an inner surface of the first sheet and/or an inner surface of the second sheet, a first pillar on the inner surface of the first sheet and/or the inner surface of the second sheet and that defines a cavity in the housing, and a second pillar on the inner surface of the first sheet and/or the inner surface of the second sheet and configured to prevent the housing from being warped when the first sheet and the second sheet are joined together by heating. The first pillar has an area that is equal to or smaller than 0.05% of the area of the housing in a plan view of the housing. The second pillar has an area that is 0.5% to 7.0% of the area of the housing in the plan view. A profile of the vapor chamber in the plan view is a substantial rectangle or a combination of substantial rectangles. The second pillar is located on an inner side of one of the substantial rectangles that is longest in a longitudinal direction and aligned so as to extend in the longitudinal direction of the longest substantial rectangle at a position passing a center point of the longest substantial rectangle. The second pillar has a length in the longitudinal direction of the longest substantial rectangle that is 30% to 70% of the length of the longest substantial rectangle. The second pillar has a width in a width direction of the longest substantial rectangle that is 5% to 10% of the width of the longest substantial rectangle.

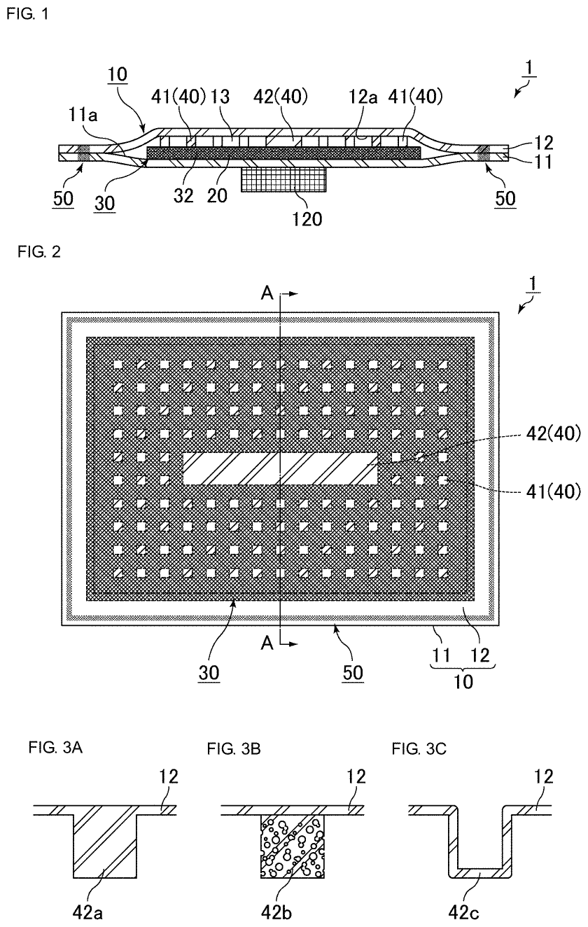

FIG. 1 is a schematic cross-sectional view of an example of a structure of a vapor chamber.

A vapor chamber 1 illustrated in FIG. 1 includes a housing 10, including a first sheet 11 and a second sheet 12 opposing each other, an operation fluid 20 enclosed in the housing 10, a wick 30 disposed on a main surface 11a of the first sheet 11 opposing the second sheet 12 (inner surface 11a of the first sheet 11), and multiple pillars 40 (first pillars 41 and a second pillar 42) disposed on a main surface 12a of the second sheet 12 opposing the first sheet 11 (inner surface 12a of the second sheet 12).

The housing 10 has a cavity 13 inside. The first sheet 11 and the second sheet 12 are supported by the first pillars 41 to secure the cavity 13.

The first sheet 11 and the second sheet 12 are joined with joining operations including heating at their outer edges that are sealed together.

In the vapor chamber 1 illustrated in FIG. 1, the wick 30 includes a mesh 32 disposed on the inner surface 11a of the first sheet 11.

The pillars 40 may be integrated with the second sheet 12. For example, the pillars 40 may be formed by etching the inner surface 12a of the second sheet 12.

Alternatively, the pillars 40 may be formed by subjecting the second sheet 12 to a process of forming protrusions and depressions.

The portion that joins the outer edges of the first sheet 11 and the second sheet 12 is a sealing portion 50.

The operation fluid 20 resides in the wick 30 in a liquid phase. The operation fluid 20 resides in the cavity 13 mainly in a gaseous phase (e.g., water vapor when the operation fluid is water).

FIG. 1 illustrates a heat source 120 installed on the main surface (outer surface) of the first sheet 11 not opposing the second sheet 12. Alternatively, the surface on which the heat source 120 is installed may be a main surface of the second sheet 12 not opposing the first sheet 11.

Heat generated by the heat source 120 vaporizes the operation fluid 20 residing in the wick 30 immediately above the heat source 120, the vaporization takes away heat from the heat source 120, and the vaporized operation fluid moves from the mesh 32 to the cavity 13.

The vaporized operation fluid 20 moves into the housing 10, and condenses near the outer edge of the housing 10 into the liquid phase.

The operation fluid 20 in the liquid phase is absorbed by the wick 30 with the capillary force of the wick 30, and moves through the wick 30 toward the heat source 120 again to take away heat from the heat source 120.

This circulating movement of the operation fluid in the housing cools the heat source with the vapor chamber.

FIG. 2 is a schematic top view of an example of a vapor chamber.

FIG. 2 is a top view of the vapor chamber 1 viewed from above the second sheet 12, while illustrating the second sheet 12 in a see-through form, to indicate the positions of the first pillars 41, the second pillar 42, and the wick 30.

FIG. 1 is a cross-sectional view of the vapor chamber taken along line A-A in FIG. 2.

In the vapor chamber 1 illustrated in FIG. 2, the housing is a substantial rectangle in a top plan view, and the sealing portion 50 has a shape extending along the outer peripheral sides of the substantial rectangle.

The outer edges of the first sheet 11 and the second sheet 12 are joined with joining operations including heating to form the sealing portion 50.

A second pillar 42 is disposed at substantially the center of the vapor chamber 1 illustrated in FIG. 2.

The position of the second pillar 42 in the vapor chamber 1 will be described in detail, later.

The inside of the second pillar may be porous or hollow.

FIGS. 3A, 3B, and 3C are schematic cross-sectional views of examples of a second pillar constituting the vapor chamber.

A second pillar 42a illustrated in FIG. 3A is integrated with the second sheet 12.

A second pillar 42b illustrated in FIG. 3B is porous inside.

A second pillar 42c illustrated in FIG. 3C is hollow inside.

The second pillar integrated with the second sheet can be obtained by, for example, a method of leaving the portion forming the second pillar while other part of the second sheet is removed by cutting or etching.

Examples of a method of obtaining a second pillar that is porous inside include a method of sintering metal particles or metal fiber on the surface of the second sheet and a method of welding metal particles or a porous sintered body of metal particles onto the surface of the second sheet.

Examples of a method of obtaining a second pillar that is hollow inside include a method of forming ribs on the surface of a flat second sheet to form protrusions on the surface of the second sheet, and a method of forming a non-through hole by laser processing in the second pillar 42a illustrated in FIG. 3A.

The pillars other than the second pillar may also be porous or hollow inside, as in the case of the second pillar.

In the vapor chamber, the first sheet and the second sheet may be formed from any material having characteristics appropriate for forming the vapor chamber, including heat conductivity, strength, and flexibility. Examples of the preferable material for the first sheet and the second sheet include metals, such as copper, nickel, aluminum, magnesium, titanium, iron, and alloys mainly containing any of these. A particularly preferable material for the first sheet and the second sheet is copper.

In the vapor chamber, the operation fluid may be any fluid that can cause gas-liquid phase changes under the environments in the housing. Examples usable as the operation fluid include water, alcohols, and CFC substitutes. The operation fluid is preferably an aqueous compound, and more preferably, water.

In the vapor chamber, the wick may be in any form that has a capillary structure that allows the operation fluid to move with the capillary force. The capillary structure of the wick may be any known structure used in an existing vapor chamber. Examples of the capillary structure include a microstructure having unevenness including pores, grooves, and protrusions. Examples of the microstructure include a porous structure, a fiber structure, a groove structure, and a network structure.

In the vapor chamber, the wick is preferably continuously formed inside the housing from an evaporator to a condenser. At least part of the wick may be integrated with the housing.

In the vapor chamber, the wick may include a mesh, non-woven fabric, or a porous body on the surface of the first sheet opposite to the inner surface. For example, the wick may include multiple protrusions arranged at predetermined intervals on the inner surface of the first sheet, and a mesh, non-woven fabric, or a porous body disposed over the protrusions. Alternatively, the wick may include a mesh, non-woven fabric, or a porous body directly disposed on the inner surface of the first sheet.

The vapor chamber is not limited to the above embodiment, and may be modified or applied to various other forms within the scope of the present invention in relation to, for example, the structure or manufacturing conditions of the vapor chamber.

For example, the vapor chamber may include a wick on the inner surface of the second sheet. Here, the pillars may support the second sheet with the wick interposed therebetween without directly coming into contact with the second sheet.

When viewed in a plan view, the vapor chamber according to the present invention has a profile of a substantial rectangle or a combination of multiple substantial rectangles.

When the profile is formed from a combination of multiple substantial rectangles, the number of substantial rectangles forming the profile is preferably equal to or smaller than five, and more preferably equal to or smaller than three.

A method for identifying the number of substantial rectangles forming the plan-view profile of the vapor chamber will be described, below.

In the vapor chamber according to the present invention, the pillars disposed on the inner surface of the first sheet and/or the inner surface of the second sheet include the first pillars defining the cavity in the housing, and the second pillar for preventing the housing from being warped due to heating performed when joining the first sheet and the second sheet together.

The first pillars are pillars for defining a cavity in the housing, and the area of each of the first pillars is equal to or smaller than 0.05% of the area of the housing in a plan view.

The entire area of all of the first pillars is preferably 1% to 20% of the area of the housing in the plan view.

The second pillar is located on the inner side of the longest substantial rectangle forming the profile of the vapor chamber in the plan view (hereinafter also referred to as a plan-view profile) and extends in the longitudinal direction of the longest substantial rectangle at a position passing the center point of the longest substantial rectangle. The center point of the substantial rectangle is a point where the diagonals of the substantial rectangle cross.

The longest substantial rectangle refers to one of the rectangles forming the plan-view profile of the vapor chamber longest in the longitudinal direction.

The length of the second pillar in the longitudinal direction of the longest substantial rectangle is 30% to 70% of the length of the longest substantial rectangle.

The width of the second pillar in the width direction of the longest substantial rectangle is 5% to 10% of the width of the longest substantial rectangle.

The area of the second pillar is 0.5% to 7.0% of the area of the housing in the plan view.

Installing the second pillar of the above dimensions at the above position prevents warpage caused by heating performed to join the first sheet and the second sheet together.

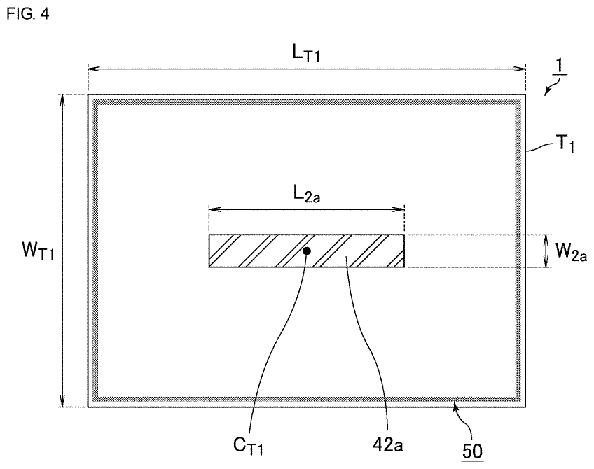

The longest substantial rectangle will now be described with reference to FIG. 4.

FIG. 4 is a top view illustrating the positional relationship between the plan-view profile of the vapor chamber and the second pillar.

As illustrated in FIG. 4, the plan-view profile of the vapor chamber 1 is one substantial rectangle T₁. Thus, the substantial rectangle T₁ serves as the longest substantial rectangle.

Here, the plan-view profile of the vapor chamber 1 indicates the profile of the entirety of the vapor chamber 1, instead of indicating only the area surrounded by the sealing portion 50.

The second pillar 42a is disposed on the inner side of the substantial rectangle T₁ to extend in the longitudinal direction of the substantial rectangle T₁ and to pass a center point C_{T1} of the substantial rectangle T₁. The second pillar 42a is disposed to extend in the longitudinal direction of the substantial rectangle T₁, and at substantially the center of the substantial rectangle T₁ in the width direction.

The plan-view profile of the vapor chamber 1 corresponds to the plan-view profile of the housing 10 constituting the vapor chamber 1. When the plan-view profile of the vapor chamber 1 is formed from a single substantial rectangle (longest substantial rectangle), the area of the substantial rectangle corresponds to the area of the housing 10 in a plan view.

A length L₂ₐ of the second pillar 42a in the longitudinal direction is 30% to 70% of a length L_{T1} of the substantial rectangle T₁ in the longitudinal direction.

A width W₂ₐ of the second pillar 42a in the width direction is 5% to 10% of a width W_{T1} of the substantial rectangle T₁ in the width direction.

The second pillar 42a having predetermined dimensions and disposed to extend in the longitudinal direction of the substantial rectangle can prevent warpage caused by heating performed to join the first sheet and the second sheet together.

The plan-view profile of the vapor chamber according to the present invention is not limited to a substantial rectangle, and may be a combination of multiple substantial rectangles.

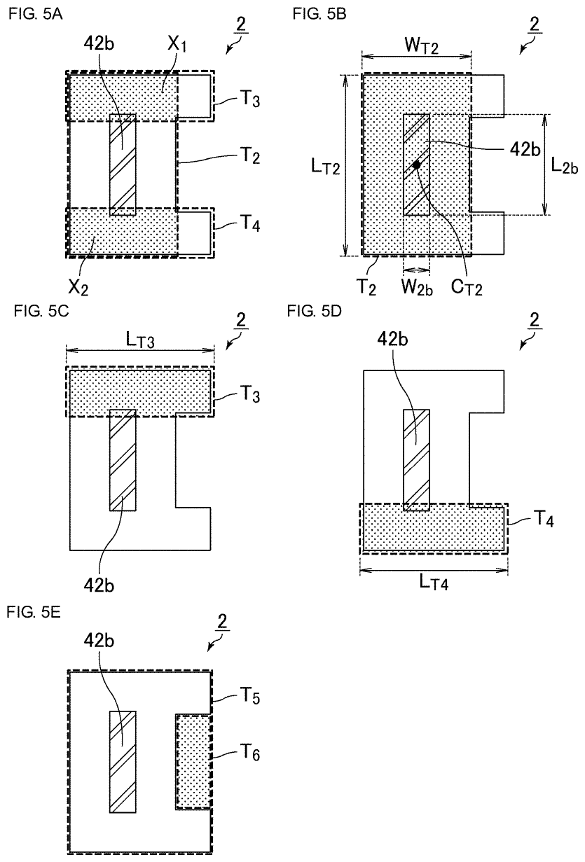

For the case where the plan-view profile of the vapor chamber is formed from a combination of multiple substantial rectangles, a method for selecting the longest substantial rectangle will be described with reference to FIGS. 5A, 5B, 5C, 5D, and 5E.

FIGS. 5A, 5B, 5C, 5D, and 5E are schematic top views of different examples of a vapor chamber.

As illustrated in FIGS. 5A, 5B, 5C, and 5D, the plan-view profile of a vapor chamber 2 is formed from a combination of a substantial rectangle T₂, a substantial rectangle T₃, and a substantial rectangle T₄. The reason why the entirety of the plan-view profile of the vapor chamber 2 is not formed from a single substantial rectangle will be described, later.

Here, the shape and the number of substantial rectangles forming a combination to constitute the plan-view profile of the vapor chamber are determined such that the number of substantial rectangles is minimum, and the sum of the lengths of all the substantial rectangles in the longitudinal direction is largest.

The substantial rectangles may have different longitudinal directions with reference to which the sum of lengths of the substantial rectangles in the longitudinal direction is calculated. The multiple substantial rectangles forming the plan-view profile of the vapor chamber do not have to be arranged without leaving a gap between each other, and may overlap each other.

In the vapor chamber 2 illustrated in FIG. 5A, the substantial rectangle T₂ and the substantial rectangle T₃ overlap each other in an area X₁, and the substantial rectangle T₂ and the substantial rectangle T₄ overlap each other in an area X₂.

As illustrated in FIGS. 5B, 5C, and 5D, the lengths of the substantial rectangle T₂, the substantial rectangle T₃, and the substantial rectangle T₄ in the longitudinal direction are denoted with L_{T2}, L_{T3}, and L_{T4}, among which L_{T2} is the longest. Thus, the substantial rectangle T₂ serves as the longest substantial rectangle. In the vapor chamber 2, the second pillar 42b is disposed to extend in the longitudinal direction of the substantial rectangle T₂ at a position passing a center point C_{T2} of the substantial rectangle T₂.

A dimension L_{2b} of the second pillar 42b in the longitudinal direction is 30% to 70% of the dimension L_{T2} of the substantial rectangle T₂ in the longitudinal direction, and a dimension W_{2b} of the second pillar 42b in the width direction is 5% to 10% of a dimension W_{T2} of the substantial rectangle T₂ in the width direction.

In the present description, the longitudinal direction of the substantial rectangle refers to the direction in which the distance between opposing two sides is longer. For a regular square, the distance between opposing two sides is equal to the distance of the other pair, and both directions serve as the longitudinal direction.

Thus, the substantial rectangles include a regular square.

In the present description, the plan-view profile of the vapor chamber is formed from a substantial rectangle or a combination of multiple substantial rectangles.

Here, the number of substantial rectangles forming the plan-view profile of the vapor chamber is preferably equal to or smaller than three, and more preferably, equal to or smaller than two.

When the number of substantial rectangles forming the plan-view profile of the vapor chamber is equal to or greater than four, the vapor chamber has a complex shape, and involves an increase in manufacturing costs.

In the present description, when the plan-view profile of the vapor chamber has a cutout (missing portion), whether the cutout is to be taken into consideration is determined depending on the area of the cutout and the area of the substantial rectangle assumed to have no cutout.

Specifically, when the rate of the area of the cutout to the area of the substantial rectangle assumed to have no cutout is equal to or smaller than 10%, the substantial rectangle is regarded as having no cutout. Thus, the entirety of the plan-view profile of the vapor chamber is regarded a single longest substantial rectangle.

On the other hand, when the rate of the area of the cutout to the area of the substantial rectangle assumed to have no cutout exceeds 10%, the substantial rectangle is divided into multiple substantial rectangles.

When the area of any of the divided substantial rectangles is equal to or smaller than 10% of the area of the plan-view profile of the vapor chamber, the substantial rectangle is excluded from the rectangles constituting the plan-view profile of the vapor chamber.

As illustrated in FIG. 5E, in the vapor chamber 2, the rate of the area of a cutout T₆ to the area of a substantial rectangle T₅ assumed to have no cutout exceeds 10% (approximately 11% in FIG. 5E). Thus, the plan-view profile of the vapor chamber 2 is regarded as being constituted of a combination of the three substantial rectangles T₂, T₃, and T₄, instead of the single substantial rectangle T₅.

If, in the vapor chamber 2 illustrated in FIG. 5E, the rate of the area of the cutout T₆ to the area of the substantial rectangle T₅ assumed to have no cutout is equal to or smaller than 10%, the substantial rectangle T₅ serves as the longest substantial rectangle.

In the vapor chamber according to the present invention, the pillars may include an even number of third pillars arranged to be substantially line symmetric with the second pillar and without in contact with the second pillar when the vapor chamber is viewed in a plan.

The area of each of the third pillars is 0.5% to 2.0% of the area of the housing in the plan view.

Installation of the third pillars prevents warpage in the width direction.

If the third pillars are in contact with the second pillar, flow of the operation fluid in the housing may be blocked, and may degrade the cooling efficiency.

The length of each of the third pillars in the width direction of the longest substantial rectangle is preferably 10% to 20% of the width of the longest substantial rectangle.

The width of each of the third pillars in the longitudinal direction of the longest substantial rectangle is preferably 2.5% to 10% of the length of the longest substantial rectangle.

Preferably, the third pillars are not in contact with the outer edge of the housing.

If the third pillars are in contact with the outer edge of the housing, flow of the operation fluid in the housing may be blocked and the cooling efficiency may be degraded.

The third pillars may be disposed to extend in the width direction or in the longitudinal direction of the longest substantial rectangle. Preferably, the third pillars extend in the width direction of the longest substantial rectangle.

As to the direction in which the third pillars extend, the dimensions of the third pillars in the longitudinal direction and the width direction are compared, and the third pillars are disposed to extend in the direction of the longer one of the dimensions.

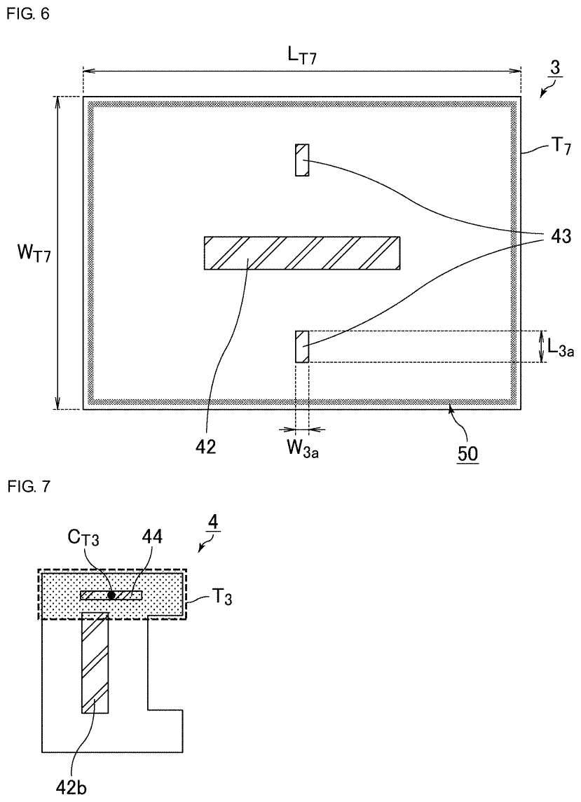

An example of a vapor chamber including the third pillars will be described with reference to FIG. 6.

FIG. 6 is a schematic top view of another example of a vapor chamber.

A vapor chamber 3 illustrated in FIG. 6 is a substantial rectangle when viewed in the plan view.

The longest substantial rectangle constituting the vapor chamber 3 is a substantial rectangle T₇.

The second pillar 42 is disposed to extend in the longitudinal direction of the substantial rectangle T₇ to pass a center point of the substantial rectangle T₇. Thus, the second pillar 42 is disposed at substantially the center of the substantial rectangle T₇ in the width direction.

An even number (two in FIG. 6) of third pillars 43 are arranged to be substantially line symmetric with respect to the second pillar 42 and without in contact with the second pillar 42.

The area of each of the third pillars 43 is preferably 0.5% to 2.0% of the area of the housing in the plan view.

The third pillars are preferably arranged to extend in the width direction of the substantial rectangle.

A length L₃ₐ of each of the third pillars 43 in the width direction of the substantial rectangle T₇ is preferably 10% to 20% of a width W_{T7} of the substantial rectangle T₇ (approximately 10.7% in FIG. 6). A width W₃ₐ of each of the third pillars in the longitudinal direction of the substantial rectangle T₇ is preferably 2.5% to 10% of a length L_{T7} of the substantial rectangle T₇ (approximately 3.0% in FIG. 6).

When the width W₃ₐ and the length L₃ₐ of each third pillar 43 are compared, the length L₃ₐ is longer than the width W₃ₐ. Thus, the third pillars 43 are disposed to extend in the width direction of the substantial rectangle T₇, serving as the longest substantial rectangle.

When the plan-view profile of the vapor chamber is constituted of a combination of multiple substantial rectangles, a fourth pillar may also be disposed on the inner side of a substantial rectangle other than the longest substantial rectangle to extend in the longitudinal direction of the substantial rectangle at a position to pass the center point of the substantial rectangle.

The length of the fourth pillar in the longitudinal direction of the substantial rectangle is preferably 30% to 70% of the length of the substantial rectangle. Preferably, the width of the fourth pillar in the width direction of the substantial rectangle is 5% to 10% of the width of the substantial rectangle.

An example of the vapor chamber including the fourth pillar will be described with reference to FIG. 7.

FIG. 7 is a schematic top view of another example of a vapor chamber.

A vapor chamber 4 illustrated in FIG. 7 corresponds to the vapor chamber 2 illustrated in FIG. 5A to which the fourth pillar is added.

As illustrated in FIG. 7, the vapor chamber 4 includes the second pillar 42b and a fourth pillar 44.

As in the case of the vapor chamber 2 illustrated in FIGS. 5A, 5B, 5C, 5D, and 5E, the vapor chamber 4 has a plan-view profile formed from a combination of the substantial rectangle T₂, the substantial rectangle T₃, and the substantial rectangle T₄. Similarly to the vapor chamber 2, the substantial rectangle T₂ serves as the longest substantial rectangle. In addition, the vapor chamber 4 includes the fourth pillar 44 disposed to pass the center point of the substantial rectangle T₃, other than the longest substantial rectangle, to extend in the longitudinal direction of the substantial rectangle T₃, to pass a center point C_{T3} of the substantial rectangle T₃.

The fourth pillar may be in contact with the second pillar, but preferably not in contact with the second pillar.

[Method for Manufacturing Vapor Chamber]

A method for manufacturing a vapor chamber may be any method with which the above structure is obtained. For example, a first sheet on which a wick is disposed and a second sheet on which the pillars including the first pillars and the second pillar are disposed are stacked one on the other, the operation fluid is poured between the sheets, and then the first sheet and the second sheet are joined together to form a vapor chamber.

A method of joining the first sheet and the second sheet together may be any method involving heating. Examples of the method include laser welding, resistance welding, diffusion bonding, solder joining, brazing, tungsten inert gas (TIG) welding, and ultrasonic joining. Among these, laser welding, brazing, or diffusion bonding is preferable.

### EXAMPLES

Embodiments more specifically describing a vapor chamber according to the present invention will be described below. The present invention is not limited to these embodiments.

### Comparative Example 1

(Manufacture of Vapor Chamber)

A copper foil sheet with plan-view dimensions of a width of 60 mm, a length of 100 mm, and a thickness of 0.2 mm was prepared to serve as a first sheet.

A copper foil sheet with plan-view dimensions of a width of 60 mm, a length of 100 mm, and a thickness of 0.08 mm was prepared to serve as a second sheet.

The first sheet was etched with persulfuric acid soda to form protrusions serving as first pillars, the first sheet and the second sheet were then bonded together while holding a mesh in between, and the outer edges of the sheets were laser-welded to obtain a housing including the first sheet and the second sheet bonded together. After welding, the operation fluid was poured through a pipe.

(Warpage Check)

The surface roughness was checked with a laser range finder and expressed in numeric form, and the difference between the highest protrusion and the lowest depression was calculated to obtain warpage of the vapor chamber.

(Heat Characteristics Check)

The vapor chamber according to Comparative Example 1 was brought into contact with a ceramic heater in the conditions of an outside temperature of 25° C., and a difference ΔT between a temperature at a position of the vapor chamber immediately above the heat source and a temperature at a position of the vapor chamber farthest from the heat source was obtained.

### Comparative Examples 2 to 3 and Examples 1 to 2

Vapor chambers according to Comparative Examples 2 to 3 and Examples 1 to 2 were formed by changing the etching pattern of the second sheet, and forming the second pillar in addition to the first pillars. Except above, the vapor chambers according to Comparative Examples 2 to 3 and Examples 1 to 2 were formed in the same procedure as in Comparative Example 1 by welding the first sheet and the second sheet together to have the second pillar at the same position as in the vapor chamber 1 illustrated in FIG. 4.

Table 1 shows the rate of the length of the second pillar in the longitudinal direction of the substantial rectangle forming the plan-view profile of the vapor chamber, the rate of the width of the second pillar in the width direction of the substantial rectangle, and the rate of the area of the second pillar with respect to the area of the housing in a plan view.

The height of the second pillar was 150 μm, as in the first pillars.

The rates [%] of the length and the width of the second pillar were calculated assuming that the plan-view profile of the vapor chamber is a rectangle with a width of 60 mm and a length of 100 mm.

### Example 3

A vapor chamber according to Example 3 was formed by changing the etching pattern of the second sheet, and forming the second pillar and the third pillars in addition to the first pillars. Except above, the vapor chamber according to Example 3 was formed in the same procedure as in Comparative Example 1 by welding the first sheet and the second sheet together to have the second pillar and the third pillar at the same positions as in the vapor chamber 3 illustrated in FIG. 6.

Table 1 shows the rates of the length of the second pillar and the width of the third pillars in the longitudinal direction of the substantial rectangle forming the plan-view profile of the vapor chamber, the rates of the width of the second pillar and the length of the third pillars in the width direction of the substantial rectangle, and the rates of the area of each of the second pillar and the third pillar with respect to the area of the housing in a plan view.

The height of each of the second pillar and the third pillars was 150 μm, as in the first pillars.

The rates [%] of the length and the width of each of the second pillar and the third pillar were calculated assuming that the plan-view profile of the vapor chamber is a rectangle with a width of 60 mm and a length of 100 mm.

(Comparison in Warpage and Heat Characteristics)

Warpage of the vapor chamber indicates the rate obtained with reference to warpage of Comparative Example 1 defined as 1.00, and warpage with the value closer to zero expresses less warpage. Thus, the rate with a value smaller than 0.9 is evaluated as “acceptable”, and the rate with a value greater than 0.9 is evaluated as “unacceptable”.

Heat characteristics indicate the rate obtained with reference to ΔT in Comparative Example 1 defined as 1.00, and heat characteristics with the value closer to 1.00 express a lower temperature at the position farthest from the heat source, that is, having preferable heat characteristics. Thus, the rate with a value equal to or greater than 0.9 is evaluated as “acceptable”, and the rate with a value smaller than 0.9 is evaluated as “unacceptable”.

Table 1 shows the comparison between warpage and heat characteristics.

TABLE 1

| | | Comparative | Comparative | | | Comparative | |
|---|---|---|---|---|---|---|---|
| | | Example 1 | Example 2 | Example 1 | Example 2 | Example 3 | Example 3 |
| First Pillar | Area Rate/ | 0.01 | 0.01 | 0.01 | 0.01 | 0.01 | 0.01 |
| | Column (%) | | | | | | |
| Second Pillar | Length Rate | — | 20 | 50 | 50 | 80 | 50 |
| | (%) | | | | | | |
| | Width Rate | — | 5 | 5 | 10 | 5 | 5 |
| | (%) | | | | | | |
| | Area Rate/ | — | 1 | 2.5 | 5 | 4 | 2.5 |
| | Column (%) | | | | | | |
| Third Pillar | Length Rate | — | — | — | — | — | 10 |
| | (%) | | | | | | |
| | Width Rate | — | — | — | — | — | 5 |
| | (%) | | | | | | |
| | Area Rate/ | — | — | — | — | — | 0.5 |
| | Column (%) | | | | | | |
| Warpage | Rate | 1.00 | 0.95 | 0.60 | 0.55 | 0.42 | 0.55 |
| | Evaluation | Unacceptable | Unacceptable | Acceptable | Acceptable | Acceptable | Acceptable |
| Heat | Rate | 1.00 | 0.99 | 0.95 | 0.91 | 0.79 | 0.92 |
| Characteristics | Evaluation | Acceptable | Acceptable | Acceptable | Acceptable | Unacceptable | Acceptable |

The results in Table 1 show that the vapor chambers according to the present invention can reduce warpage caused by joining involving heating. The results have also revealed that, the second pillar having a length in the longitudinal direction of the substantial rectangle that is smaller than 30% of the length of the substantial rectangle has scarcely any effect on warpage prevention, and the second pillar having a length in the longitudinal direction of the substantial rectangle that exceeds 70% of the length of the substantial rectangle degrades heat characteristics.

### REFERENCE SIGNS LIST

1, 2, 3, 4 vapor chamber
10 housing
11 first sheet
11a inner surface of first sheet
12 second sheet
12a inner surface of second sheet
13 cavity
20 operation fluid
30 wick
32 mesh
40 pillar
41 first pillar
42, 42a, 42b, 42c second pillar
43 third pillar
44 fourth pillar
50 sealing portion
120 heat source
C_{T1}, C_{T2}, C_{T3}, C_{T7} center point of substantial rectangle
T₁, T₂, T₃, T₄, T₅, T₇ substantial rectangle
T₆ cutout
L_{T1}, L_{T2}, L_{T3}, L_{T4}, L_{T7} length in longitudinal direction of substantial rectangle
L₂ₐ, L_{2b} length in longitudinal direction of second pillar
L₃ₐ length in longitudinal direction of third pillar
W_{T1}, W_{T2}, W_{T7} width in width direction of substantial rectangle
W₂ₐ, W_{2b} width in width direction of second pillar
W₃ₐ width in width direction of third pillar
X₁ area where substantial rectangle T₂ and substantial rectangle T₃ overlap
X₂ area where substantial rectangle T₂ and substantial rectangle T₄ overlap

1. A vapor chamber, comprising:
a housing including a first sheet and a second sheet opposing each other and having respective outer edges of the first sheet and the second sheet joined together;
an operation fluid enclosed in the housing;
a wick on an inner surface of the first sheet and/or an inner surface of the second sheet;
a first pillar on the inner surface of the first sheet and/or the inner surface of the second sheet and that defines a cavity in the housing; and
a second pillar on the inner surface of the first sheet and/or the inner surface of the second sheet and configured to prevent the housing from being warped when heated to join the first sheet and the second sheet together,
wherein a profile of the vapor chamber in a plan view is in the form of a rectangle or a combination of a plurality of rectangles, and
wherein the second pillar is located on an inner side of one of the rectangles longest in a longitudinal direction so as to extend in the longitudinal direction of the longest rectangle at a position passing a center point of the longest rectangle.

2. The vapor chamber according to claim 1,
wherein the first support column has an area that is equal to or smaller than 0.05% of an area of the housing in the plan view, and
wherein the second support column has an area that is 0.5% to 7.0% of the area of the housing in the plan view.

3. The vapor chamber according to claim 2,
wherein the second support column has a length in the longitudinal direction of the longest rectangle that is 30% to 70% of a length of the longest rectangle, and
wherein the second support column has a width in a width direction of the longest rectangle that is 5% to 10% of a width of the longest rectangle.

4. The vapor chamber according to claim 1,
wherein the second support column has a length in the longitudinal direction of the longest rectangle that is 30% to 70% of a length of the longest rectangle, and
wherein the second support column has a width in a width direction of the longest rectangle that is 5% to 10% of a width of the longest rectangle.

5. The vapor chamber according to claim 1, wherein an entire area of all of the first pillars is 1% to 20% of an area of the housing in the plan view.

6. The vapor chamber according to claim 1, further comprising:
an even number of third pillars arranged to be substantially line symmetric with the second pillar when the vapor chamber is viewed in the plan view and not in contact with the second pillar,
wherein each of the third pillars has an area that is 0.5% to 2.0% of the area of the housing in the plan view.

7. The vapor chamber according to claim 6, wherein each of the third pillars extends in the width direction of the longest rectangle.

8. The vapor chamber according to claim 7,
wherein each of the third pillars has a length in the width direction of the longest rectangle that is 10% to 20% of the width of the longest rectangle, and
wherein each of the third pillars has a width in the longitudinal direction of the longest rectangle that is 2.5% to 10% of the length of the longest rectangle.

9. The vapor chamber according to claim 1, further comprising a fourth pillar located on an inner side of a second rectangle other than the one of the rectangles longest in the longitudinal direction so as to extend in the longitudinal direction of the second rectangle at a position passing a center point of the second rectangle.

10. The vapor chamber according to claim 9, wherein the fourth pillar is not in contact with the second pillar.

11. The vapor chamber according to claim 1, wherein outer edges of the first sheet and the second sheet are welded, brazed, or diffusion bonded outer edges.

12. The vapor chamber according to claim 1, wherein at least part of the second pillar is porous.

13. The vapor chamber according to claim 1, wherein at least part of the second pillar is hollow.
